(19) United States
(12) Patent Application Publication
(10) Pub. No.: US 2009/0022621 A1
(43) Pub. Date: Jan. 22, 2009

(54) BONDING WIRE

(75) Inventors: Albrecht Bischoff, Bruchkobel (DE); Lutz Schraepler, Karlstein (DE); Holger Zingg, Biebergemund (DE)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: W.C. HERAEUS GMBH, Hanau (DE)

(21) Appl. No.: 12/278,844

(22) PCT Filed: Feb. 13, 2007
(86) PCT No.: PCT/EP2007/001233

§ 371 Date: Aug. 8, 2008

(30) Foreign Application Priority Data
Feb. 13, 2006 (DE) 10 2006 006 782.2

(51) Int. Cl. H01L 23/49; C22C 5/02

(52) U.S. Cl. 420/507

(57) ABSTRACT

The invention relates to a gold alloy containing 99 wt. %, preferably 99.9 wt. % gold, and 1 to 1000 ppm, preferably 10 to 100 ppm calcium, and 1 to 1000 ppm, preferably 10 to 100 ppm ytterbium or europium or a mixture of ytterbium and europium, as well as a method for producing a homogeneous gold alloy containing europium and/or ytterbium.

### CROSS-REFERENCE TO RELATED APPLICATIONS

This application is a Section 371 of International Application No. PCT/EP2007/001233, filed Feb. 13, 2007, which was published in the German language on Aug. 23, 2007, under International Publication No. WO 2007/093380 A1 and the disclosure of which is incorporated herein by reference.

### BACKGROUND OF THE INVENTION

The present invention relates to gold bonding wires and gold alloys with high strength suitable for these bonding wires.

In the course of the continuous miniaturization of semiconductor components and the associated goal of reducing the gold bonding wire diameter, increasing demands are placed on the strength of the wire and the reliability of the wire connections (loops). Known methods include, in particular, doping with elements of the second main group of the Periodic Table (alkaline earth metals), e.g., with beryllium and calcium according to C. W. Conti, Gold Bulletin, 32(2): 39 (1999) or Yuantao Ning, Gold Bulletin, 34(3): 77 (2001). Lanthanides, for example europium and ytterbium, are also added as doping elements. A problem with lanthanides is their solubility in the gold matrix. The poor solubility of lanthanides in the gold matrix leads to inhomogeneity and, in the least favorable case, to rough deposits in the gold chain, in particular with europium and ytterbium. Instead of an increase in strength, the opposite can also be produced, in that the doping becomes brittle or the ductility of the wire is impaired. For elements of the second main group, e.g. calcium, an increase in strength can be achieved with increasing doping concentration. Associated with this are negative ball-formation properties, so-called “dimple formation,” in the loop production.

### BRIEF SUMMARY OF THE INVENTION

An object of the present invention comprises providing gold alloys with further improved strength, in which the otherwise advantageous properties of the gold, in particular the noble character and the high conductivity, are essentially maintained.

To achieve this object, gold is alloyed in the ppm range with at least one of the lanthanides, ytterbium or europium, without simultaneously having to take into account negative ball formation properties (“dimple formation”) in the loop production. For this purpose, the gold alloy is formed as a homogeneous mixed crystal, i.e., additional phases, in particular based on europium or ytterbium, are avoided.

The introduction of europium or ytterbium into gold by gold-free master alloying, in particular together with calcium, allows homogeneous gold alloys with these lanthanides. In this way, it becomes possible, in turn, to provide gold alloys with greater than 99 wt. %, preferably greater than 99.9 wt. % gold, whose physical and mechanical properties are especially suitable for bonding wire applications.

The decisive factor here is the ability to achieve the previously not possible homogeneous distribution of europium or ytterbium as doping elements in gold through homogeneous master alloys with doping elements, particularly calcium and europium or ytterbium. In contrast to all of the other lanthanides, europium and ytterbium exhibit complete solubility in calcium, according to H. Okomoto and T. B. Massalski, Binary Alloys Phase Diagrams, Metal Park, Ohio, 44073 (1987). Binary master alloys with calcium and europium, as well as with calcium and ytterbium, have proven effective.

According to the invention, the gold alloy is thus formed as a homogenous mixed crystal. Previously unavoidable inclusions of at least one additional phase based on europium or ytterbium are avoided according to the invention. The doping elements are completely dissolved in gold at 1 to 1000 ppm, preferably 2 to 500 ppm, particularly preferably 10 to 100 ppm. In this way it is possible, in turn, to produce gold cords and gold bonding wires drawn from these cords with strength values that lie significantly above those of corresponding reference wires.

In a preferred embodiment, the gold bonding wires contain, as additional doping additives, 1 to 100 ppm cerium or cerium Misch metal. More preferred is the use of 1 to 10 ppm beryllium.

According to C. W. Conti, Gold Bulletin, 32(2): 39 (1999), these elements allow an additional increase in strength in the bonding wire, while maintaining or improving favorable bonding conditions with respect to loop and ball formation. The inventive wire qualities have tensile strength values of approximately 290 N/mm² at the comparative elongation at break value of 4% and pull test values of the bonded wire loop of approximately 20 cN (at a diameter of 30 μm).

In all cases a dimple-free, singed ball (FAB—Free Air Ball) is observed in the bonding process. (Dimples can negatively affect the joint properties between the ball and substrate).

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a graph plotting tensile strength vs. elongation at break to show the influence of various doping elements for gold bonding wires described in the Example; and

FIG. 2 is a bar graph showing fracture mode in a hook test for the various doping elements for gold wires described in the Example.

### DETAILED DESCRIPTION OF THE INVENTION

### Example

### Production of Master Alloy on a Au Basis with Calcium, Ytterbium, Ce Misch Metal, and Be Doping

From calcium and ytterbium, initially under vacuum, a homogeneous, binary master alloy is melted with 50% weight percent portions of each. This master alloy (I) is then diluted to form another master alloy (II) with the main component gold and 0.5 wt. % each of calcium and ytterbium. Together with another gold master alloy with Be and Ce Misch metal additives, this master alloy II is introduced into a gold melt.

The bonding wire starting material generated in this way has a doping concentration of 25 ppm calcium, 25 ppm ytterbium, 40 ppm Ce Misch metal (Ce-M), and 5 ppm Be.

Strength Properties

The 30-μm wire (1) drawn from the above-mentioned starting material is subjected to tensile strength testing after continuous annealing in the temperature range between 450° C. and 525° C. and compared with correspondingly produced wires with varied doping concentrations Au—Ca—Yb—Ce(M)-Be5 (2) and Au—Ca—Yb—Ce(M) (3), and also with a conventionally produced standard reference wire Au—Ca—Ce(M) (4).

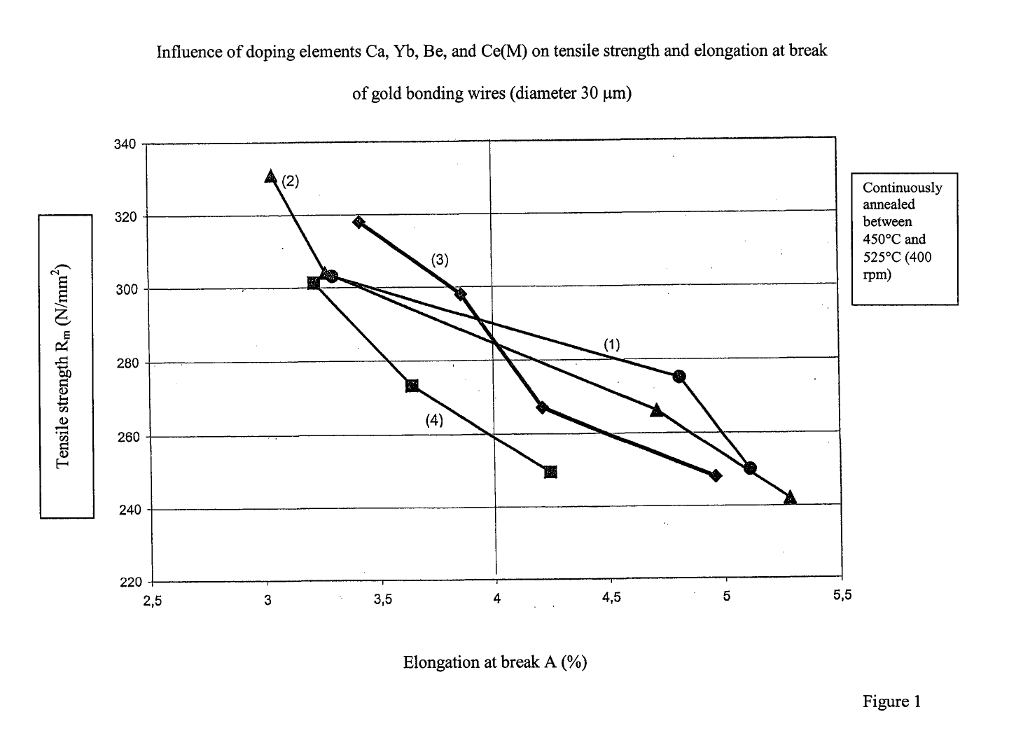

FIG. 1 shows a significantly increased tensile strength at 4% elongation at break of the bonding wires (1) to (3) produced according to embodiments of the method of the present invention relative to the reference wire (4). In the former case, the tensile strength lies at approximately 290 N/mm², and in the latter case, the tensile strength lies at 260 N/mm².

Bonding Properties

Wires annealed to 4% are subjected to a Ball-Wedge bonding process according to ASTM, 100 Barr, Harbor Drive, West Conshohocken, Pa. 19428-2959 and G. G. Harman, Wire Bonding in Microelectronics, pages 67ff, McGraw-Hill (1997). The quality of the bondability or the stability of the loops is tested by the so-called pull or hook test according to MIL STD 883F, Microcircuits, Method 2011.7.

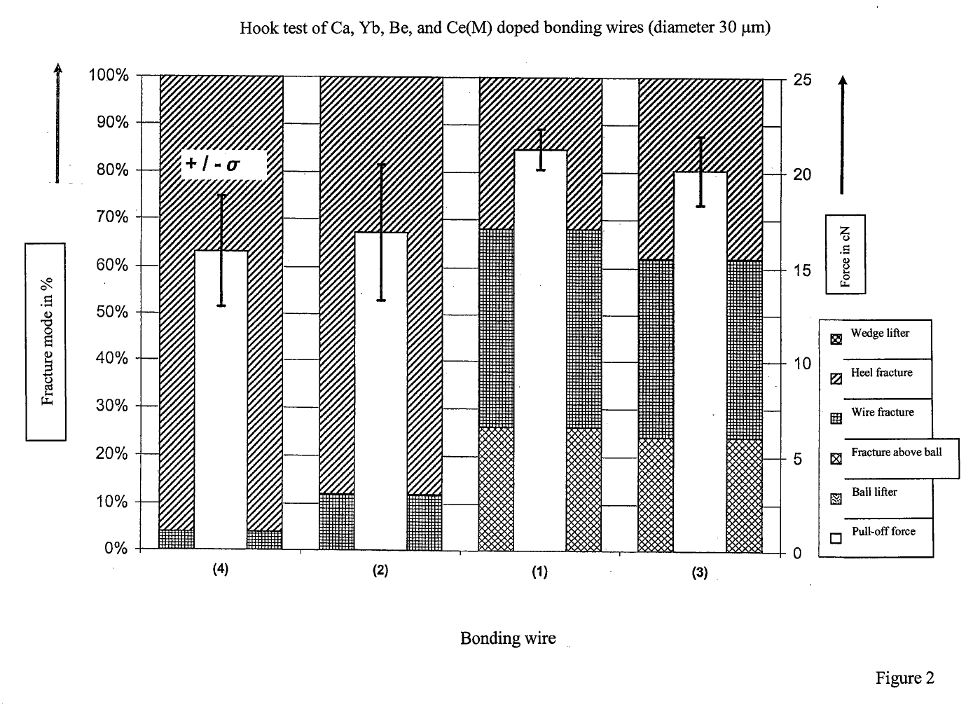

FIG. 2 shows significantly improved pull forces for the wires (1) to (3) produced according to embodiments of the method of the present invention relative to the reference wire (4). In the former case, the pull forces lie between 17 and 22 cN (in the Example, bonding wire (1) lies at 22 cN) compared to 16 cN for reference wire (4)). The wires of the invention also exhibit a significantly reduced proportion of the least favorable heel-break mode, which strongly limits the reliability of the bond connection. For the wire (1) of the Example it is approximately 32%, and for the reference wire according to (4) it is 97%.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1-4. (canceled)

5. A gold alloy containing 99 wt. % gold, 1 to 1000 ppm calcium and 1 to 1000 ppm of a lanthanide selected from ytterbium, europium and mixtures of ytterbium and europium, wherein the gold alloy has a form of a homogeneous mixed crystal.

6. The gold alloy according to claim 5, wherein the alloy contains 99.9 wt. % gold, 10 to 100 ppm calcium, and 10 to 100 ppm of the lanthanide.

7. A method for producing a homogeneous, single-phase gold alloy containing a lanthanide selected from europium, ytterbium and mixtures of europium and ytterbium, wherein the lanthanide is dissolved in gold as a homogeneous master alloy consisting exclusively of doping elements.

8. The method according to claim 7, wherein the homogeneous master alloy is a calcium master alloy.

9. A calcium-doped bonding wire comprising a gold alloy containing 99.9 wt. % gold, 1 to 1000 ppm calcium and 1 to 1000 ppm of a lanthanide selected from ytterbium, europium and mixtures of ytterbium and europium, wherein the gold alloy has a form of a homogeneous mixed crystal.

10. The calcium-doped bonding wire according to claim 9, wherein the gold alloy contains 99.9 wt % gold, 10 to 100 ppm calcium and 10 to 100 ppm of the lanthanide.
